(19) United States
(12) Patent Application Publication
(10) Pub. No.: US 2025/0089476 A1
(43) Pub. Date: Mar. 13, 2025

(54) DISPLAY DEVICE

(71) Applicant: SAMSUNG DISPLAY CO., LTD., Yongin-si (KR)

(72) Inventors: SUN WOO LEE, Yongin-si (KR); RAN KIM, Yongin-si (KR); UIYOUNG PARK, Yongin-si (KR)

(21) Appl. No.: 18/674,046

(22) Filed: May 24, 2024

(30) Foreign Application Priority Data
Sep. 11, 2023 (KR) 10-2023-0120460

(51) Int. Cl. H10K 59/124; G09G 3/32; H10K 59/121

(52) U.S. Cl. CPC H10K 59/124; H10K 59/1213; G09G 3/32; G09G 2300/0426; G09G 2300/0819; G09G 2300/0842

(57) ABSTRACT

A display device according to an embodiment includes a barrier layer on a substrate and including a trench, a first buffer layer on the barrier layer and arranged along a profile of the trench, a second buffer layer on the first buffer layer and arranged along a profile of the first buffer layer, a semiconductor layer on the second buffer layer and including a channel region overlapping the trench, a gate insulating layer on the semiconductor layer and overlapping the channel region, and a gate electrode on the gate insulating layer and overlapping the channel region, and a thickness of the first buffer layer is thinner than a thickness of the second buffer layer.

### CROSS-REFERENCE TO RELATED APPLICATION

The present application claims priority to and the benefit of Korean Patent Application No. 10-2023-0120460, filed on Sep. 11, 2023 in the Korean Intellectual Property Office, the entire disclosure of which is incorporated herein by reference.

### BACKGROUND

### 1. Field

Aspects of embodiments of the present disclosure relate to a display device.

### 2. Description of the Related Art

A display device is a device that displays an image, including a liquid crystal display (LCD), an organic light emitting diode (OLED), a quantum dot light emitting diode (QLED), and a microLED display, etc.

Such a display device includes a pixel, and the pixel may include a light emitting element, such as an organic light emitting element or an inorganic light emitting element.

A display device including a light emitting element and a transistor that controls an amount of current flowing through the light emitting element.

Recently, as display devices have come to have higher resolution and dead space in display devices has decreased, an area where transistors are placed may decrease.

Accordingly, the electrical characteristics of the transistor disposed in a relatively small area may deteriorate.

### SUMMARY

According to an aspect of embodiments of the present disclosure, a display device with improved device reliability is provided. According to another aspect of embodiments of the present disclosure, a display device including a transistor with improved device characteristics is provided. According to another aspect of embodiments of the present disclosure, the device characteristics of the transistor are improved by including a relatively long channel region in a limited area.

According to another aspect of embodiments of the present disclosure, step coverage issues and device reliability in transistors including trench and/or fin structures is improved.

According to one or more embodiments of the present disclosure, a display device includes a barrier layer on a substrate and including a trench, a first buffer layer on the barrier layer and arranged along a profile of the trench, a second buffer layer on the first buffer layer and arranged along a profile of the first buffer layer, a semiconductor layer on the second buffer layer and including a channel region overlapping the trench, a gate insulating layer on the semiconductor layer and overlapping the channel region, and a gate electrode on the gate insulating layer and overlapping the channel region, and a thickness of the first buffer layer is thinner than a thickness of the second buffer layer.

The trench may include a vertical portion connecting a portion having a thinnest thickness of the barrier layer and a portion having a thickest thickness of the barrier layer, the channel region may have a depth corresponding to the vertical portion of the trench, and the depth of the channel region may be 330 Å to 3500 Å.

A width of the channel region may be 5 μm or less.

The first buffer layer may include a material of which a hydrogen emission amount increases as a stack thickness increases.

The second buffer layer may include a material of which a hydrogen emission amount is constant as a stack thickness increases.

The first buffer layer may include silicon nitride, and the second buffer layer may include silicon oxide.

The first buffer layer may have a thickness of 330 Å to 1100 Å, and the second buffer layer may have a thickness of 1600 Å to 2400 Å.

A thickness of the gate insulating layer may be 650 Å or more and 2000 Å or less.

A corner portion of the trench may have a rounded shape.

The gate insulating layer may include at least one of Al₂O₃, TiO₂, and HfO₂.

According to one or more embodiments of the present disclosure, a display device includes a barrier layer on a substrate and including a fin structure, a first buffer layer on the barrier layer and arranged along a profile of the fin structure, a second buffer layer on the first buffer layer and arranged along a profile of the first buffer layer, a semiconductor layer on the second buffer layer and including a channel region overlapping the fin structure, a gate insulating layer on the semiconductor layer and overlapping the channel region, and a gate electrode on the gate insulating layer and overlapping the channel region, and a thickness of the first buffer layer is thinner than a thickness of the second buffer layer.

The fin structure may includes a vertical portion connecting a portion having a thinnest thickness of the barrier layer and a portion having a thickest thickness of the barrier layer, the channel region may have a depth corresponding to the vertical portion of the fin structure, and the depth of the channel region may be 330 Å to 3500 Å.

A width of the channel region may be 5 μm or less.

The first buffer layer may include a material of which a hydrogen emission amount increases as a stack thickness increases.

The second buffer layer may include a material of which a hydrogen emission amount is constant as a stack thickness increases.

The first buffer layer may include silicon nitride, and the second buffer layer may include silicon oxide.

The first buffer layer may have a thickness of 450 Å or less, and the second buffer layer may have a thickness of 1000 Å to 2000 Å.

A thickness of the gate insulating layer may be 650 Å or more and 2000 Å or less.

A corner portion of the fin structure may have a rounded shape.

The gate insulating layer may include at least one of Al₂O₃, TiO₂, and HfO₂.

According to an aspect of one or more embodiments, the device characteristics of the transistor are improved by securing a relatively long channel region in a limited area.

According to another aspect of one or more embodiments, a display device with improved device reliability in a transistor including a trench and/or fin structure is provided.

### BRIEF DESCRIPTION OF THE DRAWINGS

FIG. 1 is a plan view of a display device according to an embodiment.

FIG. 2 is a circuit diagram of a pixel of a display device according to an embodiment.

FIG. 3 to FIG. 6 are cross-sectional views of a display device according to some embodiments.

FIG. 7 is a diagram for explaining a relationship between a thickness of a silicon oxide film and a defect rate according to an embodiment.

FIG. 8 is a diagram for explaining an amount of hydrogen emission according to a thickness of a gate insulating layer according to an embodiment.

FIG. 9 is a diagram for explaining an amount of hydrogen emission according to a thickness of each layer of a buffer layer according to an embodiment.

FIG. 10 and FIG. 11 are circuit diagrams of a pixel of a display device according to some embodiments.

DESCRIPTION OF SYMBOLS

| | |
|---|---|
| SUB: substrate; | BAR: barrier layer |
| BUF: buffer layer; | BF1: first buffer layer |
| BF2: second buffer layer; | TCH: trench |
| FIN: fin; | ACT: semiconductor layer |
| CA: channel region; | GI: gate insulating layer |
| GE: gate electrode; | V1, V2: vertical portion |
| T1, T2, T3, T4, T5, T6, T7: transistor | |

### DETAILED DESCRIPTION

Herein, with reference to the attached drawings, various embodiments will be described in further detail so that those skilled in the art can easily implement the present invention.

However, the present invention may be implemented in many different forms and is not limited to the embodiments described herein.

In order to more clearly explain the present invention, parts that are not relevant to the description may be omitted, and same or similar components are assigned the same reference numerals throughout the specification.

In addition, the size and thickness of each component shown in the drawings may be shown arbitrarily for convenience of explanation, and the present invention is not necessarily limited to that which is shown.

In the drawings, thicknesses may be enlarged to more clearly show or explain various layers and regions. For example, in the drawings, for convenience of explanation, the thicknesses of some layers and regions may be exaggerated.

Additionally, when a part of a layer, membrane, region, or plate is said to be “above” or “on” another part, this includes not only a case in which it is directly above another part, but also cases in which there is another part or parts therebetween.

By contrast, when a part is said to be “right on top” or “directly on top” of another part, it means that there is no other part therebetween.

In addition, being “above” or “on” a reference part means being located above or below the reference part, and does not necessarily mean being located “above” or “on” the reference part in a direction opposite to gravity.

In addition, throughout the specification, when a part is said to “include” a certain component, this means that it may further include other components rather than excluding other components, unless specifically stated to the contrary.

In addition, throughout the specification, when reference is made to “on a plane,” this means when the target portion is viewed from above, and when reference is made to “in cross-section,” this means when a cross-section of the target portion is cut vertically and viewed from a side.

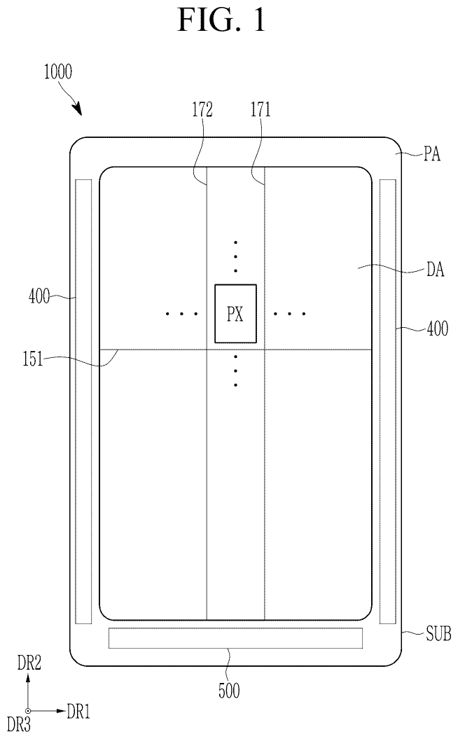

FIG. 1 is a plan view of a display device according to an embodiment.

Referring to FIG. 1, a display device 1000 according to an embodiment may be, for example, an organic light emitting display device, a plasma display device, a field emission display device, a quantum dot display device, a microLED display device, a liquid crystal display device, etc.

In the following description, the description is centered on an example in which the display device 1000 is an organic light emitting display device, but embodiments are not limited thereto.

The display device 1000 includes a display area DA including a plurality of pixels PX, which are units capable of displaying images, and a substrate SUB including a peripheral area PA around the display area DA.

The plurality of pixels PX may be disposed overall in the display area DA.

For example, the plurality of pixels PX may be arranged in a matrix form in the display area DA.

The peripheral area PA includes pixels PX capable of displaying an image and may or may not display an image.

The substrate SUB may have a surface parallel to a first direction DR1 and a second direction DR2 perpendicular thereto, and a direction perpendicular upward to the surface of the substrate SUB may be formed in a third direction DR3.

A plurality of signal lines or a plurality of voltage lines that are electrically connected to the pixel PX and can apply a signal or driving voltage may be located in the display area DA.

The plurality of signal lines or multiple voltage lines may include multiple scan lines 151 that can transmit scan signals to pixels PX, multiple data lines 171 that can transmit data signals to pixels PX, and multiple driving voltage lines 172 that can transmit driving voltages to pixels PX.

Each pixel PX may include at least one driving element (e.g., a transistor, etc.), a light emitting element (e.g., an organic light emitting diode, etc.), and a capacitor connected to the driving element.

The light emitting element may emit light by receiving a signal from the driving device.

In an embodiment, the first scan line 151 may be extended across the display area DA in approximately the first direction DR1, and the driving voltage line 172 and data line 171 can be extended in approximately the second direction DR2.

In the peripheral area PA, there may be located a scan driver 400 that can supply scan signals connected to multiple scan lines 151, and a data driver 500 that can supply data signals connected to multiple data lines 171, etc.

The scan driver 400 may include a transistor formed directly on the substrate along with a transistor located in the display area DA.

FIG. 1 illustrates an example in which the scan driver 400 is located on both left and right sides of the display area DA, but depending on an embodiment, the scan driver 400 may be located only on one side of the display area DA.

In an embodiment, the data driver 500 may be formed as an integrated circuit and may be mounted on a substrate SUB or a circuit board connected to the substrate SUB.

The data driver 500 may apply a driving voltage to the driving voltage line 172.

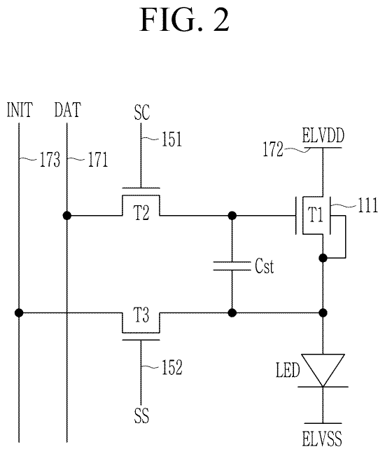

FIG. 2 is an equivalent circuit diagram of a pixel of a display device according to an embodiment.

A pixel PX of the display device may include a pixel circuit part containing multiple transistors T1, T2, T3 and a storage capacitor Cst, and at least one light emitting element LED that is connected to the pixel circuit part.

In addition, depending on an embodiment, the pixel circuit part may further include a light emitting unit capacitor (not shown) connected to both ends of the light emitting element LED.

In the present embodiment, the description will mainly be based on an example in which one pixel PX includes one light emitting device ED.

In an embodiment, a plurality of transistors T1, T2, T3 are formed of one driving transistor T1 (also referred to as a first transistor) and two switching transistors T2, T3 divided into an input transistor T2 (also referred to as a second transistor) and an initialization transistor T3 (also referred to as a third transistor).

Each of the transistors T1, T2, T3 includes a gate electrode, a first electrode, and a second electrode, and also includes a semiconductor layer including a channel, such that current flows or blocks the channel of the semiconductor layer depending on a voltage of the gate electrode.

Here, one of the first and second electrodes may be a source electrode and the other may be a drain electrode depending on the voltage applied to each transistor T1, T2, T3.

The gate electrode of the driving transistor T1 is connected to a first end of the storage capacitor Cst, and is also connected to the second electrode (output electrode) of the input transistor T2.

In addition, the first electrode of the driving transistor T1 is connected to the driving voltage line 172 that transmits a driving voltage ELVDD, and the second electrode of the driving transistor T1 is connected to an electrode (anode) of the light emitting element LED, and a second end of the storage capacitor Cst and the first electrode of the initialization transistor T3.

The driving transistor T1 receives the data voltage DAT to the gate electrode according to the switching operation of the input transistor T2, and can supply a driving current to the light emitting element LED according to the voltage of the gate electrode.

At this time, the storage capacitor Cst stores and maintains the voltage of the gate electrode of the driving transistor T1.

The gate electrode of the driving transistor T1 may face a conductive pattern 111, and the conductive pattern 111 may be electrically connected to the second electrode of the driving transistor T1 and the anode of the light emitting element LED.

The gate electrode of the input transistor T2 is connected to the first scan line 151 that transmits the first scan signal SC, and the first electrode of the input transistor T2 transmits the data voltage DAT or the reference voltage, and is connected to the transmittable data line 171, and the second electrode of the input transistor T2 is connected to one end of the storage capacitor Cst and the gate electrode of the driving transistor T1.

The input transistor T2 may be turned on according to the first scan signal SC to transmit the reference voltage or data voltage DAT to the gate electrode of the driving transistor T1 and one end of the storage capacitor Cst.

The gate electrode of the initialization transistor T3 is connected to the second scan line 152 that transmits a second scan signal SS.

The first electrode of the initialization transistor T3 is connected to the second end of the storage capacitor Cst, the second electrode of the driving transistor T1, and one electrode (anode) of the light emitting element LED, and the second electrode of the initialization transistor T3 is connected to the initialization voltage line 173 that delivers an initialization voltage INIT.

The initialization transistor T3 is turned on according to the second scan signal SS, delivering the initialization voltage INIT to the anode of the light emitting element LED and the second end of the storage capacitor Cst, thereby initializing the voltage of the anode of the light emitting element LED.

The first end of the storage capacitor Cst is connected to the gate electrode of the driving transistor T1, and the second end is connected to the first electrode of the initialization transistor T3, the second electrode of the driving transistor T1, and the anode of the light emitting element LED.

The cathode of the light emitting element LED is connected to a common voltage line that transmits a common voltage ELVSS.

The output current of the driving transistor T1 is transmitted to the anode of the light emitting element LED, the cathode of the light emitting element LED receives a common voltage through a common voltage line, the light emitting element LED receives the output current of the driving transistor T1, and light is emitted according to the output current to display a gray scale.

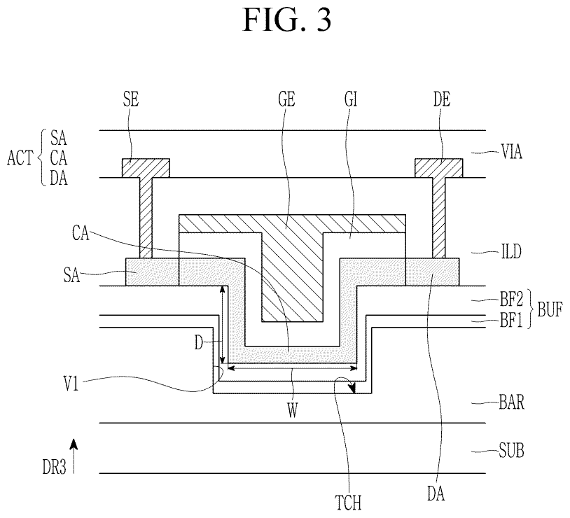

Herein, a structure of a transistor included in a pixel of a display device according to an embodiment will be described with reference to FIGS. 3 to 6.

For convenience of explanation, FIGS. 3 to 6 do not show the light emitting element LED, but only briefly show the structure of the transistor located below the light emitting element LED.

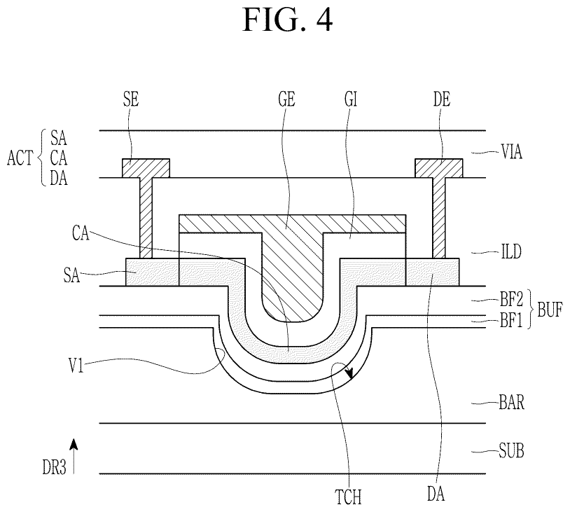

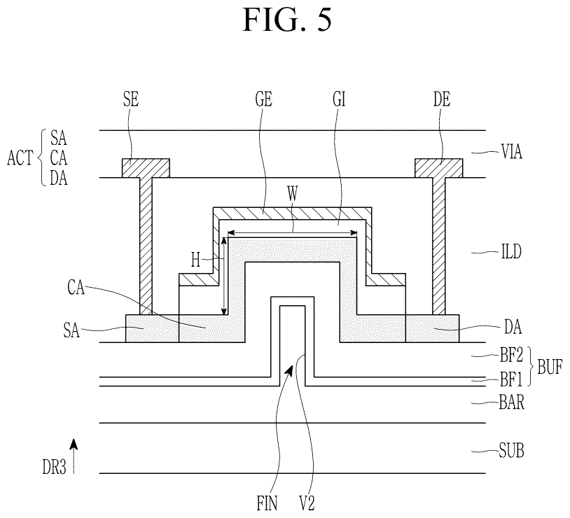

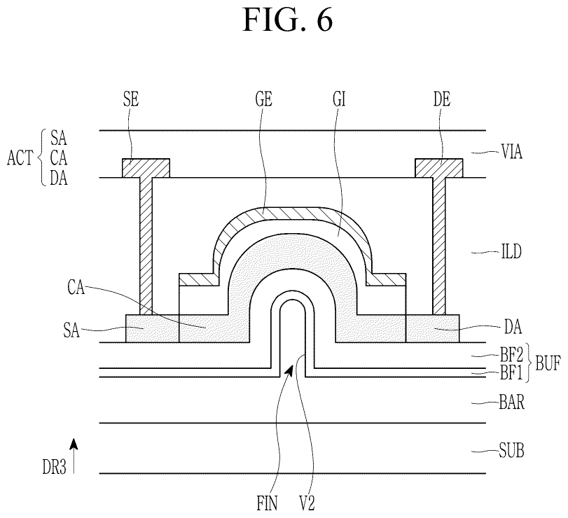

FIGS. 3 and 4 are cross-sectional views of some embodiments in which the transistor includes a trench structure; and FIGS. 5 and 6 are cross-sectional views of some embodiments in which the transistor includes a fin structure.

Referring to FIGS. 3 and 4, a display device according to an embodiment may include a substrate SUB.

In an embodiment, the substrate SUB may be a rigid substrate, such as a glass substrate.

In another embodiment, the substrate SUB may be a flexible substrate capable of bending, folding, rolling, etc.

For example, the substrate SUB may include a polymer resin, such as polyimide (PI), polyamide (PA), or polyethylene terephthalate (PET).

The substrate SUB may have a single layer or multiple layers.

In an embodiment, the substrate SUB may have at least one base layer containing a polymer resin and at least one inorganic layer alternately stacked sequentially.

A barrier layer BAR is located on the substrate SUB.

The barrier layer BAR can block impurities, etc. from flowing through the substrate SUB.

The barrier layer BAR may be formed of an inorganic insulating material such as silicon nitride (SiNₓ), silicon oxide (SiOₓ), or silicon oxynitride (SiOₓN_{y}).

These materials can be used alone or in combination with each other.

The barrier layer BAR may include a trench TCH.

The trench TCH may be formed from a top of the barrier layer BAR toward the substrate SUB.

A thickness of the barrier layer BAR in a portion where the trench TCH is formed may be thinner than a thickness of the barrier layer BAR in a portion where the trench TCH is not formed.

Depending on an embodiment, the trench TCH may penetrate the barrier layer BAR in the thickness direction to expose a top surface of the substrate SUB.

The trench TCH formed in the barrier layer BAR may include a vertical portion V1.

The vertical portion V1 is a portion that connects the upper surface of the barrier layer BAR in the area where the trench TCH is not formed and the upper surface of the barrier layer BAR in the area where the trench TCH is formed in a generally vertical direction.

In cross-section, the vertical portion V1 may correspond to a portion connecting a thinnest portion of the barrier layer BAR and a thickest portion of the barrier layer BAR.

Depending on an embodiment, when the trench TCH penetrates the barrier layer BAR to expose the upper surface of the substrate, the length of the vertical portion V1 of the trench TCH may be the same as the thickness of the barrier layer BAR.

The length of the vertical portion V1 of the trench TCH may be from several hundred Å to several thousand Å.

For example, the length of the vertical portion V1 may be approximately 330 Å to 3500 Å.

The length of the vertical portion V1 of the trench TCH may correspond to a depth D of a channel region CA of a semiconductor layer ACT.

If the length of the vertical portion V1 of the trench TCH is less than about 330 Å, it may be difficult to secure a sufficient channel length of the semiconductor layer ACT, which may worsen a short-channel phenomenon.

The short-channel phenomenon refers to a phenomenon in which a distance between a source and a drain is shortened because the channel does not have sufficient length, and, as a result, the gate does not function properly as a switch, resulting in leakage current and deterioration of device performance.

On the other hand, if the length of the vertical portion V1 of the trench TCH is longer than about 3500 A, as the step of the trench TCH increases, the thickness of the film adjacent to the channel area CA of the semiconductor ACT (for example, a buffer layer BUF, a gate insulating layer GI, etc.) becomes thinner in the vertical portion than in the horizontal part, intensifying the step coverage phenomenon, this can cause differences in the device characteristics of the transistor.

The buffer layer BUF may be located on the barrier layer BAR.

The buffer layer BUF may prevent or substantially prevent penetration of unnecessary components, such as impure elements or moisture, when forming the semiconductor layer ACT.

In an embodiment, the buffer layer BUF may include any of silicon nitride (SiNₓ), silicon oxide (SiOₓ), silicon oxynitride (SiOₓN_{y}), and amorphous silicon (Si).

These materials can be used alone or in combination with each other.

The buffer layer BUF may overlap the trench TCH formed in the barrier layer BAR.

The buffer layer BUF may be formed along a profile of the trench TCH formed in the barrier layer BAR.

Being formed along a profile may mean being formed with a step corresponding to a step of the upper surface of the lower layer.

In a case of the upper layer being formed along the profile, the upper layer has a step corresponding to the lower layer, but the overall thickness may be constant.

The buffer layer BUF formed along the profile of the barrier layer BAR may have a step corresponding to a step of the upper surface of the barrier layer BAR and may be formed to have an overall constant thickness.

The buffer layer BUF may have a single layer or multiple layers.

In an embodiment, as shown in FIG. 3, the buffer layer BUF may include a first buffer layer BF1 and a second buffer layer BF2.

The first buffer layer BF1 may be located on the barrier layer BAR, and the second buffer layer BF2 may be located on the first buffer layer BF1.

The first buffer layer BF1 and the second buffer layer BF2 may overlap the trench TCH formed in the barrier layer BAR.

The first buffer layer BF1 may be formed along the profile of the trench TCH formed in the barrier layer BAR, and the second buffer layer BF2 may be formed along a profile of the first buffer layer BF1.

The first buffer layer BF1 formed along the profile of the barrier layer BAR may have a step corresponding to the step of the upper surface of the barrier layer BAR and may have a constant overall thickness, and the first buffer layer BF1 and the second buffer layer BF2 formed along the profile may have a step corresponding to the step of the upper surface of the first buffer layer BF1 and may have a constant overall thickness.

Depending on an embodiment, a third buffer layer (not shown) may be further positioned on the second buffer layer BF2.

The third buffer layer may be formed along a profile of the second buffer layer BF2 and may overlap the trench TCH formed in the barrier layer BAR.

In an embodiment, a thickness of the first buffer layer BF1 may be thinner than a thickness of the second buffer layer BF2.

In an embodiment, the first buffer layer BF1 may include a material of which a hydrogen emission amount increases as a stack thickness increases.

In an embodiment, the second buffer layer BF2 may include a material of which a hydrogen emission amount is constant even as a stack thickness increases.

In an embodiment, for example, the first buffer layer BF1 may include silicon nitride (SiNₓ), and the second buffer layer BF2 may include silicon oxide (SiOₓ).

As will be described later, silicon nitride (SiNₓ) emits a larger amount of hydrogen per unit area than silicon oxide (SiOₓ), and, accordingly, hydrogen is over-injected into the semiconductor layer ACT formed later, resulting in leakage current, and this may cause a deterioration in characteristics.

Accordingly, the thickness of the first buffer layer BF1 including silicon nitride (SiNₓ) may be formed to be thinner than the thickness of the second buffer layer BF2 including silicon oxide (SiOₓ).

In an embodiment, the thickness of the first buffer layer BF1 containing silicon nitride (SiNₓ) may be formed to be approximately 330 Å to 1100 Å, and the thickness of the second buffer layer BF2 containing silicon oxide (SiOₓ) may be formed to be approximately 1600 Å to 2400 Å.

Depending on an embodiment, the second buffer layer BF2 may have a thickness of about 2400 Å or more.

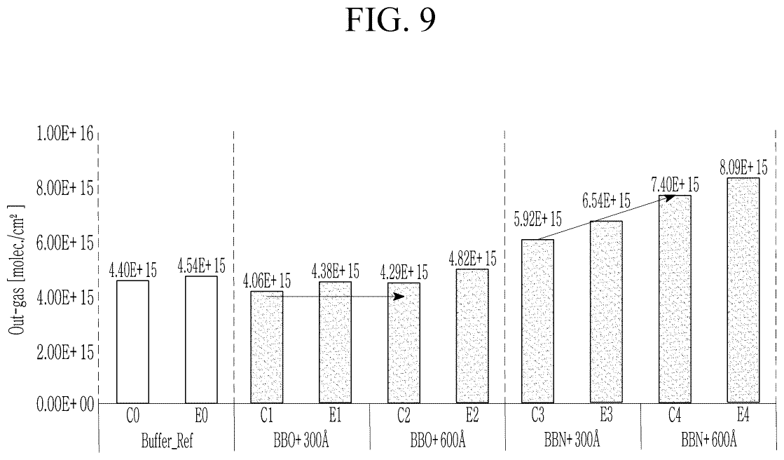

Herein, as will be described later with reference to FIG. 9, an amount of hydrogen released by silicon nitride (SiNₓ) increases with the stack thickness, but there is little change in an amount of hydrogen released by silicon oxide (SiOₓ) depending on the stack thickness.

Therefore, by stacking the second buffer layer BF2 layer thickly containing silicon oxide (SiOₓ), hydrogen diffusion can be controlled and a sufficiently effective channel length can be secured.

In addition, embodiments of the present invention can prevent or substantially prevent changes in device characteristics due to step coverage and improve device reliability by limiting the thickness of silicon nitride (SiNₓ), which has a high hydrogen emission rate, in the buffer layer BUF, and adjusting the thickness of silicon oxide (SiOₓ), which has a low hydrogen emission rate.

The semiconductor layer ACT is located on the buffer layer BUF.

The semiconductor layer ACT may include an oxide semiconductor.

Oxide semiconductors include at least one of indium (In), tin (Sn), zinc (Zn), gallium (Ga), titanium (Ti), zirconium (Zr), hafnium (Hf), aluminum (Al), and oxygen (O).

For example, the semiconductor layer ACT may include one or more of ITO, IGZO, ITGZO, or IGTO.

Depending on an embodiment, the semiconductor layer ACT may include a silicon semiconductor.

The semiconductor layer ACT may include a first area SA and a second area DA that are spaced apart from each other, and a channel region CA therebetween.

The first area SA and the second area DA may be doped with impurities to have conductivity.

Depending on an embodiment, the semiconductor layer ACT may further include lightly doped drain (LDD) regions at both ends of the channel region CA.

The channel region CA may be formed to have a trench along the profile of the second buffer layer BF2.

Since the second buffer layer BF2 is formed according to the profile of the first buffer layer BF1, and the first buffer layer BF1 is formed according to the profile of the trench TCH formed in the barrier layer BAR, the channel region CA may be formed according to the profile of the trench TCH formed in the barrier layer BAR.

In this way, the channel region CA may overlap the trench TCH formed in the barrier layer BAR, and may have a depth D corresponding to the length of the vertical portion V1 of the trench TCH.

The depth D of the channel region CA may be mainly determined by the length of the vertical portion V1 of the trench TCH formed in the barrier layer BAR.

In an embodiment, the depth D of the channel region CA may be approximately 330 Å to 3500 Å.

If the depth D of the channel region CA is less than about 330 Å, it is difficult to secure sufficient channel length, and if the depth D is greater than about 3500 Å, step coverage problems with adjacent insulating layers may occur, and the device characteristics of the transistor may deteriorate.

A width W of the channel region CA may be determined depending on a width of the trench TCH formed in the barrier layer BAR and the thickness of the buffer layer BUF.

In an embodiment, the width W of the channel region CA may be formed to be about 5 μm or less.

For example, the width W of the channel region CA may be formed to be about 3 μm to about 5 μm.

If the width W of the channel region CA is less than about 3 μm, a short-channel phenomenon may occur.

Meanwhile, if the width W of the channel region CA is greater than about 5 μm, it may be difficult to provide a display device with sufficiently high resolution.

However, depending on an embodiment, the width W of the channel region CA may be formed to be about 3 μm or less.

Since the channel region CA according to an embodiment includes a trench structure, the depth D of the channel region CA can be adjusted even when the width W of the channel region CA is narrow (about 3 μm or less), and, as a result, it is possible to secure sufficient channel length, thereby mitigating a short-channel phenomenon, and providing a high-resolution display device with improved device reliability.

A gate insulating layer GI is located on the semiconductor layer ACT.

In an embodiment, the gate insulating layer GI may include silicon nitride (SiNₓ), silicon oxide (SiOₓ), or silicon oxynitride (SiOₓN_{y}).

These materials can be used alone or in combination with each other.

The gate insulating layer GI may have a single layer or multiple layers.

Additionally, the gate insulating layer GI may include a material having a high dielectric constant, for example, Al₂O₃, TiO₂, HfO₂, etc., to improve the insulating properties.

The gate insulating layer GI may be formed along the profile of the channel region CA of the semiconductor layer ACT.

The gate insulating layer GI may be positioned to overlap the channel region CA of the semiconductor layer ACT.

In an embodiment, the gate insulating layer GI may have a thickness of about 2000 Å or less.

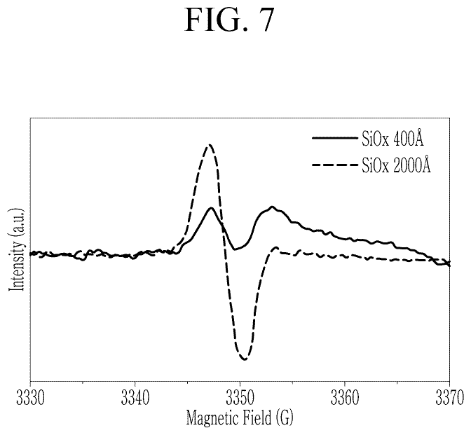

As will be described later with reference to FIG. 7, if the thickness of the gate insulating layer GI increases, defects in the device may increase and characteristics thereof may deteriorate.

Therefore, in an embodiment, the thickness of the gate insulating layer GI is about 2000 Å or less.

As the thickness of the gate insulating layer GI becomes thinner, leakage current may increase.

In an embodiment, the gate insulating layer GI thickness to reduce the defect rate while minimizing or reducing leakage current may be in a range from 650 Å to 2000 Å.

A gate conductive layer including a gate electrode GE may be positioned on the gate insulating layer GI.

In an embodiment, the gate conductive layer may include any of molybdenum (Mo), aluminum (Al), copper (Cu), titanium (Ti), and a metal oxide, and may be a single layer or multiple layers containing these.

The gate electrode GE may overlap the channel region CA.

In an embodiment, the gate electrode GE is formed in a same process as the gate insulating layer GI and may have a same planar shape.

The gate electrode GE may be positioned to overlap the semiconductor layer ACT and the substrate SUB in a direction perpendicular to the surface.

An interlayer insulating layer ILD may be located on the semiconductor layer ACT and the gate electrode GE.

In an embodiment, the interlayer insulating layer ILD may include silicon nitride (SiNₓ), silicon oxide (SiOₓ), or silicon oxynitride (SiOₓN_{y}), and may be a single layer or multiple layers containing these.

When the interlayer insulating layer ILD has multiple layers and contains silicon nitride and silicon oxide, the layer containing silicon nitride may be located closer to the substrate SUB than the layer containing silicon oxide.

A data conductive layer including a first electrode SE and a second electrode DE is positioned on the interlayer insulating layer ILD.

In an embodiment, the data conductive layer is any of aluminum (Al), silver (Ag), magnesium (Mg), gold (Au), nickel (Ni), chromium (Cr), calcium (Ca), molybdenum (Mo), and titanium (Ti), tungsten (W), and/or copper (Cu) and metal oxide, and may be a single layer or multiple layers containing these.

The first electrode SE may be in contact with the first area SA of the semiconductor layer ACT through an opening formed in the interlayer insulating layer ILD.

The second electrode DE may be in contact with the second area DA of the semiconductor layer ACT through an opening formed in the interlayer insulating layer ILD.

An insulating film VIA is located on the data conductive layer.

The insulating film VIA may include any of organic insulating materials such as general-purpose polymers, such as polymethylmethacrylate (PMMA) or polystyrene (PS), polymer derivatives with phenolic groups, acrylic polymers, imide polymers, polyimide, and siloxane polymers.

Although not shown, a light emitting element LED including an anode, a light emitting layer, and a cathode may be located on the insulating film VIA.

FIG. 4 is a cross-sectional view of a display device according to an embodiment.

The embodiment of FIG. 4 differs from the embodiment of FIG. 3 in that corners of the trench TCH are rounded.

For the same components as those in the embodiment of FIG. 3, the description of FIG. 3 may not be repeated.

A buffer layer BUF and a semiconductor layer ACT may be formed along the profile of the trench TCH formed in the barrier layer BAR.

Being formed along a profile may mean being formed with a step corresponding to the step of the upper surface of the lower layer.

In the case of the upper layer formed along the profile, the upper layer has a step corresponding to the lower layer, but the overall thickness may be constant.

In an embodiment, the channel region CA of the semiconductor layer ACT formed along the profile of the barrier layer BAR may include a gently parabolic corner portion corresponding to the corner rounding of the trench TCH formed in the barrier layer BAR.

Accordingly, a short-channel phenomenon caused by a concentration of electric fields in the corners can be reduced.

In addition, since a decrease in threshold voltage due to electric field concentration can be prevented or substantially prevented, device performance can be further improved.

FIG. 5 and FIG. 6 are cross-sectional views of a display device according to some embodiments.

FIG. 5 and FIG. 6 are cross-sectional views including a transistor including a fin structure.

Further detailed description of a same configuration as the previously described embodiments may be omitted.

Referring to FIG. 5, the substrate SUB is provided.

The substrate SUB may be a rigid substrate or a flexible substrate capable of bending, folding, rolling, etc.

The substrate SUB may be a single layer or multiple layers.

In an embodiment, the substrate SUB may have at least one base layer containing a polymer resin sequentially stacked and at least one inorganic layer alternately stacked.

A barrier layer BAR including a fin FIN structure is located on the substrate SUB.

The fin FIN structure may be formed to protrude from the upper surface of the barrier layer BAR.

A thickness of the barrier layer BAR in an area where the fin FIN structure is formed may be thicker than a thickness of the barrier layer BAR in an area where the fin FIN structure is not formed.

That is, the height of the top surface of the barrier layer BAR in the area where the fin FIN structure is formed may be higher than the height of the top surface of the barrier layer BAR in the area where the fin FIN structure is not formed.

The fin FIN structure formed in the barrier layer BAR may include a vertical portion V2.

The vertical portion V2 may be a section that generally connects the upper surface of the barrier layer BAR in the area where the fin FIN structure is formed and the upper surface of the barrier layer BAR in the area where the fin FIN structure is not formed, in a vertical direction.

In cross-section, the vertical portion V2 of the fin FIN structure may correspond to a portion connecting a thinnest portion of the barrier layer BAR and a thickest portion of the barrier layer BAR.

A length of the vertical portion V2 of the fin FIN structure may be from several hundred Å to several thousand Å.

In an embodiment, for example, the length of the vertical portion V2 may be between about 330 Å and about 3500 Å.

The length of the vertical portion V2 of the fin FIN structure may correspond to a height H of the channel region CA of the semiconductor layer ACT.

If the length of the vertical portion V2 of the fin FIN structure is less than about 330 Å, it is difficult to secure sufficient channel length, and if the length is larger than about 3500 Å, the buffer layer BUF, the gate insulating layer GI, etc. are required in a subsequent process. As step coverage problems become more severe during processing, differences in transistor device characteristics may occur.

A buffer layer BUF may be located on the barrier layer BAR.

The buffer layer BUF may be formed along the profile of the fin FIN structure formed in the barrier layer BAR.

In an embodiment, the buffer layer BUF may include any of silicon nitride (SiNₓ), silicon oxide (SiOₓ), silicon oxynitride (SiOₓN_{y}), and amorphous silicon (Si).

These materials can be used alone or in combination with each other.

The buffer layer BUF may overlap the fin FIN structure formed in the barrier layer BAR.

The buffer layer BUF may be formed along the profile of the fin FIN structure formed in the barrier layer BAR.

Being formed along a profile may mean being formed with a step corresponding to the step of an upper surface of the lower layer.

In the case of the upper layer formed along the profile, the upper layer has a step corresponding to the lower layer, but the overall thickness may be constant.

The buffer layer BUF may be a single layer or multiple layers.

In the embodiment shown in FIG. 5, the buffer layer BUF may include a first buffer layer BF1 and a second buffer layer BF2.

The first buffer layer BF1 may be located on the barrier layer BAR, and the second buffer layer BF2 may be located on the first buffer layer BF1.

The first buffer layer BF1 and the second buffer layer BF2 may overlap the fin FIN structure formed in the barrier layer BAR.

The first buffer layer BF1 may be formed along the profile of the fin FIN structure formed on the barrier layer BAR, and the second buffer layer BF2 may be formed along the profile of the first buffer layer BF1.

In an embodiment, a third buffer layer (not shown) may be further positioned on the second buffer layer BF2.

The third buffer layer may be formed along a profile of the second buffer layer BF2 and may overlap the fin FIN structure formed in the barrier layer BAR.

In an embodiment, a thickness of the first buffer layer BF1 may be thinner than a thickness of the second buffer layer BF2.

The first buffer layer BF1 may include a material of which a hydrogen emission amount increases as a stack thickness increases.

The second buffer layer BF2 may include a material of which a hydrogen emission amount is constant even as a stack thickness increases.

In an embodiment, for example, the first buffer layer BF1 may include silicon nitride (SiNₓ), and the second buffer layer BF2 may include silicon oxide (SiOₓ).

As will be described later, silicon nitride (SiNₓ) emits a larger amount of hydrogen per unit area than silicon oxide (SiOₓ), and, accordingly, hydrogen is over-injected into the semiconductor layer ACT formed later, resulting in leakage current, which may cause a deterioration in characteristics.

Accordingly, the thickness of the first buffer layer BF1 including silicon nitride (SiNₓ) may be formed to be thinner than the thickness of the second buffer layer BF2 including silicon oxide (SiOₓ).

In an embodiment, the first buffer layer BF1 including silicon nitride (SiNₓ) has a thickness of about 450 Å or less, and the second buffer layer BF2 including silicon oxide (SiOₓ) has a thickness of about 1000 Å, and, in an embodiment, may be formed to a thickness of about 2000 Å or more.

Herein, as will be described later in FIG. 9, an amount of hydrogen released by silicon nitride (SiNₓ) increases with the thickness of the stack, but there is little change in the amount of hydrogen released by silicon oxide (SiOₓ) depending on a thickness of the stack.

Therefore, by stacking the second buffer layer BF2 containing silicon oxide (SiOₓ) thicker, device reliability can be improved by preventing or substantially preventing changes in device characteristics due to step coverage while securing sufficiently effective channel length.

The semiconductor layer ACT is located on the buffer layer BUF.

The semiconductor layer ACT may include an oxide semiconductor.

The oxide semiconductor may include at least one of indium (In), tin (Sn), zinc (Zn), gallium (Ga), titanium (Ti), zirconium (Zr), hafnium (Hf), aluminum (Al) and oxygen (O).

In an embodiment, for example, the semiconductor layer ACT may include one or more of ITO, IGZO, ITGZO, or IGTO.

Depending on an embodiment, the semiconductor layer ACT may include a silicon semiconductor.

The semiconductor layer ACT may include a first area SA and a second area DA that are spaced apart from each other, and a channel region CA therebetween.

The first area SA and the second area DA may be doped with impurities to have conductivity.

Depending on an embodiment, the semiconductor layer ACT may further include a lightly doped drain (LDD) between both ends of the channel region CA and the first region SA and the second region DA.

The channel region CA may be formed to have a fin FIN structure along a profile of the second buffer layer BF2.

Since the second buffer layer BF2 is formed according to the profile of the first buffer layer BF1, and the first buffer layer BF1 is formed according to the profile of the fin FIN structure formed in the barrier layer BAR, the channel region CA may be formed according to the profile of the fin FIN structure formed in the barrier layer BAR.

In this way, the channel region CA may overlap the fin FIN structure formed in the barrier layer BAR, and may have the height H corresponding to the length of the vertical portion V2 of the fin FIN structure.

The height H of the channel region CA may be mainly determined by the length of the vertical portion V2 of the fin FIN structure formed in the barrier layer BAR.

In an embodiment, the height H of the channel region CA may be formed to be about 330 Å to 3500 Å.

If the height H of the channel region CA is less than about 330 Å, it is difficult to secure sufficient channel length, and if the height H is greater than about 3500 Å, step coverage problems with adjacent insulating layers may occur, which may deteriorate the device characteristics of the transistor.

A width W of the channel region CA may be determined depending on the width of the fin FIN structure formed in the barrier layer BAR and a thickness of the buffer layer BUF.

In an embodiment, the width W of the channel region CA may be formed to be about 5 μm or less.

In an embodiment, for example, the width W of the channel region CA may be about 3 μm to 5 μm.

If the width W of the channel region CA is less than about 3 μm, a short-channel phenomenon may occur, and if the width W of the channel region CA is larger than about 5 μm, it is difficult to provide a display device with sufficiently high resolution.

However, depending on an embodiment, the width W of the channel region CA may be formed to be about 3 μm or less.

Since the channel region CA according to an embodiment includes a fin FIN structure, the height H of the channel region CA can be adjusted even when the width W of the channel region CA is narrow (about 3 μm or less), and, as a result, it is possible to secure a sufficient channel length, thereby mitigating a short-channel phenomenon, and providing a high-resolution display device with improved device reliability.

The gate insulating layer GI is located on the semiconductor layer ACT.

In an embodiment, the gate insulating layer GI may include silicon nitride (SiNₓ), silicon oxide (SiOₓ), or silicon oxynitride (SiOₓN_{y}).

These materials can be used alone or in combination with each other.

Additionally, the gate insulating layer GI may include a material having a high dielectric constant, for example, Al₂O₃, TiO₂, HfO₂, etc., to improve the insulating properties.

The gate insulating layer GI may be a single layer or multiple layers.

The gate insulating layer GI may be formed along a profile of the channel region CA of the semiconductor layer ACT.

The gate insulating layer GI may be positioned to overlap the channel region CA of the semiconductor layer ACT.

In an embodiment, the gate insulating layer GI may have a thickness of about 2000 Å or less.

As will be described later with reference to FIG. 7, if the thickness of the gate insulating layer GI increases, defects in the device may increase and characteristics may deteriorate.

Therefore, in an embodiment, the thickness of the gate insulating layer GI is about 2000 Å or less.

As the thickness of the gate insulating layer GI becomes thinner, leakage current may increase.

In an embodiment, the gate insulating layer GI thickness to reduce the defect rate while minimizing or reducing leakage current may be in a range from 650 Å to 2000 Å.

The gate conductive layer including a gate electrode GE may be positioned on the gate insulating layer GI.

In an embodiment, the gate conductive layer may include any of molybdenum (Mo), aluminum (Al), copper (Cu), titanium (Ti), and metal oxide, and may be a single layer or multiple layers containing these.

An interlayer insulating layer ILD may be located on the semiconductor layer ACT and the gate electrode GE.

In an embodiment, the interlayer insulating layer ILD may include any of silicon nitride (SiNₓ), silicon oxide (SiOₓ), or silicon oxynitride (SiOₓN_{y}), and may be a single layer or multiple layers containing these.

A data conductive layer including a first electrode SE and a second electrode DE is positioned on the interlayer insulating layer ILD.

In an embodiment, the data conductive layer may include any of aluminum (Al), silver (Ag), magnesium (Mg), gold (Au), nickel (Ni), chromium (Cr), calcium (Ca), molybdenum (Mo), titanium (Ti), tungsten (W), and/or copper (Cu) and metal oxide, and may be a single layer or multiple layers containing these.

The first electrode SE may be in contact with the first area SA of the semiconductor layer ACT through an opening formed in the interlayer insulating layer ILD.

The second electrode DE may be in contact with the second area DA of the semiconductor layer ACT through an opening formed in the interlayer insulating layer ILD.

An insulating film VIA is located on the data conductive layer.

The insulating film VIA may include any of organic insulating materials such as general-purpose polymers, such as polymethylmethacrylate (PMMA) or polystyrene (PS), polymer derivatives with phenolic groups, acrylic polymers, imide polymers, polyimide, and siloxane polymers.

FIG. 6 is a cross-sectional view of a display device according to an embodiment.

The embodiment of FIG. 6 differs from the embodiment of FIG. 5 in that corners of the fin FIN structure are rounded.

For the same components as the embodiment of FIG. 5, description thereof may not be repeated.

The buffer layer BUF and the semiconductor layer ACT may be formed along a profile of the fin FIN structure formed in the barrier layer BAR.

Being formed along a profile may mean being formed with a step corresponding to the step of the upper surface of the lower layer.

In the case of the upper layer formed along the profile, the upper layer has a step corresponding to the lower layer, but the overall thickness may be constant.

In an embodiment, the channel region CA of the semiconductor layer ACT formed along the profile of the barrier layer BAR may include a gently parabolic corner portion corresponding to the corner rounding of the fin FIN structure of the barrier layer BAR.

Accordingly, a short-channel phenomenon caused by the concentration of electric fields in the corners can be reduced.

In addition, since a decrease in threshold voltage due to electric field concentration can be prevented or substantially prevented, device performance can be further improved.

FIG. 7 is a diagram illustrating a relationship between a thickness of silicon oxide (SiOₓ) and device defects according to an embodiment.

FIG. 7 is a spectrum graph of an electron spin resonance (ESR) test of a thin film in which silicon oxide (SiOₓ) was deposited to a thickness of 400 Å and a thin film in which silicon oxide (SiOₓ) was deposited to a thickness of 2000 Å. The results obtained through the electron spin resonance test are shown in Table 1 below.

In electron spin resonance testing, a number of spins per unit area is proportional to the defect density.

TABLE 1

| silicon oxide (SiOₓ) thickness (Å) | defect density (spins/cm²) |
|---|---|
| 400 | 4.8E+12 |
| 2000 | 3.9E+13 |

Referring to FIG. 7 and Table 1, it can be seen that the defect density is large when silicon oxide (SiOₓ) is deposited more thickly.

That is, the greater the thickness of the silicon oxide (SiOₓ) the higher a concentration of oxygen deficiency regions and/or hydrogen, such that the amount of hydrogen injected into the semiconductor layer increases, which may deteriorate device characteristics.

In an embodiment, the thickness of the insulating layer containing silicon oxide (SiOₓ) located adjacent to the semiconductor layer is formed to be about 2000 Å or less to manage device characteristics.

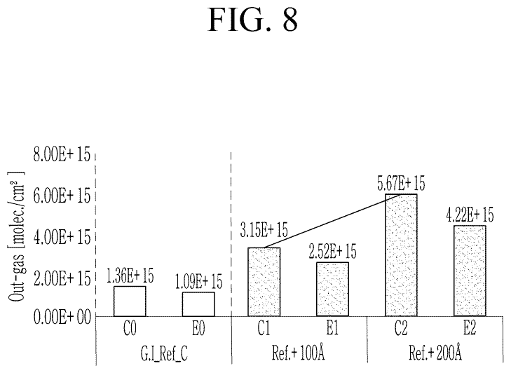

FIG. 8 is a diagram for explaining an amount of hydrogen emission according to a thickness of the gate insulating layer according to an embodiment.

FIG. 8 shows samples (C0, E0) in which the gate insulating layer GI has a reference thickness (Ref) and a sample in which the gate insulating layer GI has a thickness (Ref+100 Å) 100 Å greater than the reference thickness according to an embodiment; this is the result of simulating the hydrogen emission amount of samples (C1, E1) and samples (C2, E2) in which the gate insulating layer GI has a thickness (Ref+200 Å) that is 200 Å greater than the reference thickness.

Referring to FIG. 8, it can be seen that an amount of hydrogen emission increases as the thickness of the gate insulating layer GI increases.

In this way, if the thickness of the gate insulating layer GI is thick, the amount of hydrogen released increases, and, thus, the amount of hydrogen injected into the semiconductor layer increases, and the effective channel region decreases, which may lead to deterioration of device characteristics.

FIG. 9 is a diagram for explaining an amount of hydrogen emission according to a thickness of each buffer layer according to an embodiment.

According to an embodiment, the buffer layer BUF is a multi-layer structure consisting of a layer (BBO) containing silicon oxide (SiOₓ) and a layer (BBN) containing silicon nitride (SiNₓ), and the hydrogen emission amount was tested by varying the thickness of each layer.

FIG. 9 shows samples (C0, E0) in which the buffer layer BUF has a reference thickness (Ref), and the layer (BBO) containing silicon oxide (SiOₓ) of the buffer layer BUF has a thickness 300 Å greater than the reference thickness (BBO+300 Å), and the samples (C2, E2) in which the layer (BBO) containing silicon oxide (SiOₓ) of the buffer layer BUF have a thickness of 600 Å greater than the reference thickness (BBO+600 Å). A graph shows a sample (C3, E3) in which the layer (BBN) containing silicon nitride (SiNₓ) of the buffer layer BUF has a thickness (BBN+300 Å) 300 Å greater than the reference thickness, and the silicon nitride of the buffer layer BUF, and this graph shows the amount of hydrogen emission from samples (C4, E4) in which the layer (BBN) containing (SiNₓ) has a thickness (BBN+600 Å) that is 600 Å greater than the reference thickness.

Referring to FIG. 9, it can be seen that changes in the thickness of the layer (BBO) containing silicon oxide (SiOₓ) of the buffer layer BUF have little effect on the amount of hydrogen emission.

On the other hand, it can be seen that the amount of hydrogen emission increases as the thickness of the layer (BBN) containing silicon nitride (SiNₓ) of the buffer layer BUF increases.

In this way, when the thickness of the layer (BBN) of the buffer layer BUF containing silicon nitride (SiNₓ) is thick, the amount of hydrogen released increases, and, accordingly, the amount of hydrogen injected into the semiconductor layer increases and the effective channel region decreases, which may result in deterioration of device characteristics.

Meanwhile, the layer (BBO) containing silicon oxide (SiOₓ) of the buffer layer BUF can control the thickness of the buffer layer BUF without changing the characteristics of the device by adjusting the thickness (BBO) of the layer containing silicon oxide (SiOₓ), as the amount of hydrogen emission is similar to the standard sample (CO, E0) even when the thickness increases.

In an embodiment, the thickness of the layer (BBN) containing silicon nitride (SiNₓ) of the buffer layer BUF is controlled to a level of about 330 Å to about 1100 Å to limit the amount of hydrogen emission, and the layer containing silicon oxide (SiOₓ). The thickness of the (BBO) can be controlled to about 1600 Å to 2400 Å such that the buffer layer BUF is sufficiently thick without increasing the amount of hydrogen released from the buffer layer BUF.

Depending on an embodiment, the thickness of the layer (BBO) containing silicon oxide (SiOₓ) may be formed as thick as 2400 Å or more.

In this way, according to an embodiment, the buffer layer BUF has a sufficient thickness and can be controlled to keep the hydrogen emission amount of the buffer layer BUF constant, such that a step coverage problem caused by the trench or fin FIN structure can be improved, and device defects can be minimized or reduced.

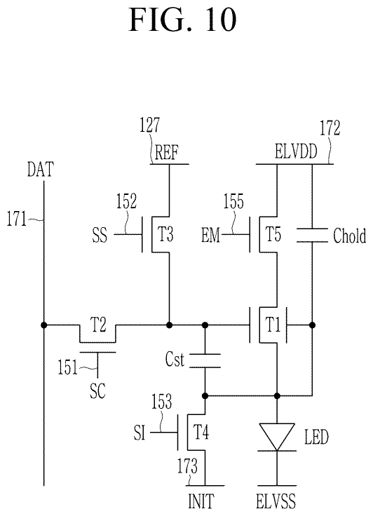

FIG. 10 is a circuit diagram of a pixel of a display device according to an embodiment.

The pixel according to FIG. 10 includes a plurality of transistors T1, T2, T3, T4, T5 connected to various wirings 127, 151, 152, 153, 155, 171, 172, 173, and a storage capacitor Cst, a hold capacitor Chold, and a light emitting element LED.

Here, transistors and capacitors excluding the light emitting element LED constitute the pixel circuit part, and one pixel may include the pixel circuit part and the light emitting element.

A plurality of wires 127, 151, 152, 153, 155, 171, 172, and 173 are connected to one pixel PX.

The plurality of wires include a reference voltage line 127, a first scan line 151, a second scan line 152, a third scan line 153, a light emission control line 155, a data line 171, a driving voltage line 172, and an initialization voltage line 173.

Additionally, a common voltage line transmitting a common voltage ELVSS may be connected to a side of the light emitting element LED.

The first scan line 151 transmits a first scan signal SC to the gate electrode of the second transistor T2, and the second scan line 152 transmits a second scan signal SS to the gate electrode of the third transistor T3.

The third scan line 153 transmits a third scan signal SI to the gate electrode of the fourth transistor T4, and the light emission control line 155 transmits an emission signal EM to the gate electrode of the fifth transistor T5.

The data line 171 is a wiring that delivers a data voltage DAT generated from a data driving part (not shown). Accordingly, a size of a luminous current delivered to the light emitting element LED changes, which in turn changes the luminance of the light emitting element LED.

The driving voltage line 172 applies a driving voltage ELVDD.

The reference voltage line 127 delivers a reference voltage REF, and the initialization voltage line 173 delivers an initialization voltage INIT.

In an embodiment, each of the voltages applied to the driving voltage line 172, the reference voltage line 127, and the initialization voltage line 173 may be constant voltages.

It is a transistor that adjusts the size of the light emitting current output to one electrode (anode) of the light emitting element LED according to a size of the voltage (i.e., a voltage stored in the storage capacitor Cst) of the gate electrode (herein also referred to as a driving gate electrode or a first driving gate electrode) of the driving transistor T1.

The size of the light emitting current output to one electrode (anode) of the light emitting element LED can be adjusted according to the data voltage DAT applied to the pixel.

To this end, the first electrode of the driving transistor T1 is arranged to receive the driving voltage ELVDD and is connected to the driving voltage line 172 via the fifth transistor T5.

Meanwhile, the second electrode of the driving transistor T1 outputs a light emitting current to the light emitting element LED and is connected to one electrode (anode) of the light emitting element LED.

The data voltage DAT is applied to the driving gate electrode of the driving transistor T1 through the second transistor T2.

Meanwhile, the driving gate electrode of the driving transistor T1 is connected to one electrode (herein referred to as a second storage electrode) of the storage capacitor Cst.

Accordingly, a voltage of the gate electrode of the driving transistor T1 changes according to the voltage stored in the storage capacitor Cst, and the light emitting current output by the driving transistor T1 changes accordingly.

The storage capacitor Cst serves to keep the voltage of the gate electrode of the driving transistor T1 constant during one frame.

Meanwhile, the driving gate electrode of the driving transistor T1 is also connected to the third transistor T3 and can be initialized by receiving the reference voltage REF.

Additionally, the driving transistor T1 may further include an overlapping electrode (herein also referred to as a second driving gate electrode) that overlaps a channel located in the semiconductor layer, and the overlapping electrode is one electrode (anode) of the light emitting element LED. It is connected to the second electrode of the fourth transistor T4 and the second electrode of the hold capacitor Chold.

The overlapping electrode (second driving gate electrode) is connected to one electrode (anode) of the light emitting element LED, such that the characteristics of the driving transistor T1 can be maintained without change during the light emission period.

The second transistor T2 is a transistor that receives the data voltage DAT into the pixel.

The gate electrode of the second transistor T2 is connected to the first scan line 151.

The first electrode of the second transistor T2 is connected to the data line 171, and the second electrode of the second transistor T2 is connected to the driving gate electrode of the driving transistor T1, the second electrode of the third transistor T3, and the second storage electrode of the storage capacitor Cst.

When the second transistor T2 is turned on by the positive polarity voltage of the first scan signal SC transmitted through the first scan line 151, the data voltage DAT transmitted through the data line 171 is turned on, and is transmitted to the driving gate electrode of the driving transistor T1, and, at this time, the data voltage DAT is stored in the second storage electrode of the storage capacitor Cst.

Depending on an embodiment, a parasitic capacitor is provided between the first scan line 151 and the driving gate electrode of the driving transistor T1 (or the second storage electrode of the storage capacitor Cst or the second electrode of the third transistor T3), and a type of boost capacitor (not shown) may be formed.

The third transistor T3 transmits the reference voltage REF to the driving gate electrode of the driving transistor T1 and the second storage electrode of the storage capacitor Cst.

The gate electrode of the third transistor T3 is connected to the second scan line 152, and the first electrode of the third transistor T3 is connected to the reference voltage line 127.

The second electrode of the third transistor T3 is connected to the second storage electrode of the storage capacitor Cst, the driving gate electrode of the driving transistor T1, and the second electrode of the second transistor T2.

The third transistor T3 is turned on by the positive voltage of the second scan signal SS received through the second scan line 152, and, at this time, the reference voltage REF is applied to the driving transistor T1, and is initialized by passing it to the gate electrode and the second storage electrode of the storage capacitor Cst.

The fourth transistor T4 serves to initialize one electrode (anode) of the light emitting element LED.

Herein, the fourth transistor T4 is also referred to as a light emitting diode initialization transistor.

When initializing one electrode (anode) of the light emitting element LED, the fourth transistor T4 is connected to the overlapping electrode (second driving gate electrode) of the driving transistor T1, the first storage electrode of the storage capacitor Cst, and the second electrode of the hold capacitor Chold is also initialized.

The gate electrode of the fourth transistor T4 is connected to the third scan line 153, and the second electrode of the fourth transistor T4 is one electrode of the light emitting element LED and an overlapping electrode (second driving gate electrode) of the driving transistor T1, a first storage electrode of the storage capacitor Cst, and the second electrode of the hold capacitor Chold, and the first electrode of the fourth transistor T4 is connected to the initialization voltage line 173.

When the third scan line 153 is turned on by the positive voltage of the third scan signal SI, the initialization voltage INIT is applied to the first electrode of the light emitting element LED, the an overlapping electrode (second drive gate electrode) of the drive transistor T1, the first storage electrode of the storage capacitor Cst, and the second electrode of the hold capacitor Chold, initializing them.

The fifth transistor T5 transmits the driving voltage ELVDD to the first electrode of the driving transistor T1.

The gate electrode of the fifth transistor T5 is connected to the light emission control line 155, the first electrode of the fifth transistor T5 is connected to the driving voltage line 172, and the second electrode of the fifth transistor T5 is connected to the first electrode of the driving transistor T1.

When the fifth transistor T5 is turned on by the positive polarity voltage of the light emission signal EM flowing through the light emission control line 155, the driving voltage ELVDD is applied to the first electrode of the driving transistor T1.

The first storage electrode of the storage capacitor Cst is connected to the second electrode of the fourth transistor T4, the second electrode of the drive transistor T1, the overlapping electrode (second drive gate electrode) of the drive transistor T1, and the light emitting element LED, and the second electrode of the hold capacitor Chold, and the second storage electrode is connected to the gate electrode of the driving transistor T1, the second electrode of the third transistor T3, and the second electrode of the second transistor T2.

The storage capacitor Cst serves to keep the voltage of the driving gate electrode of the driving transistor T1 constant during one frame.

The first electrode of the hold capacitor Chold is connected to the driving voltage line 172, and the second electrode of the hold capacitor Chold is connected to the overlapping electrode (second driving gate electrode) of the driving transistor T1, one electrode (anode) of the light emitting element LED, the second electrode of the fourth transistor T4, and the first storage electrode of the storage capacitor Cst.

The hold capacitor Chold ensures that the voltage of the overlapping electrode (second driving gate electrode) of the driving transistor T1 and one electrode (anode) of the light emitting element LED is constant, and, in particular, serves to keep it constant during the light emission period.

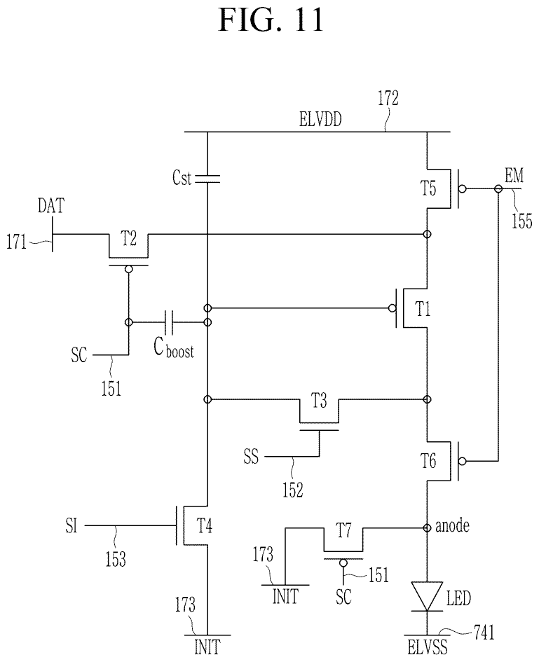

FIG. 11 is a circuit diagram of a pixel of a display device according to an embodiment.

The pixel according to FIG. 11 includes a plurality of transistors T1, T2, T3, T4, T5, T6, T7 connected to various wires 151, 152, 153, 155, 171, 172, 741, 173, a storage capacitor Cst, a boost capacitor Cboost, and a light emitting element LED.

However, depending on an embodiment, the boost capacitor Cboost may be omitted.

The plurality of wires 151, 152, 153, 155, 171, 172, 741, and 173 are connected to one pixel PX.

The plurality of wires include a first scan line 151, a second scan line 152, a third scan line 153, a light emission control line 155, a data line 171, a driving voltage line 172, a common voltage line 741, and a initialization voltage line 173.

The first scan line 151 transmits the first scan signal SC to the second transistor T2 and a seventh transistor T7.

A voltage of opposite polarity to the voltage applied to the first scan line 151 may be applied to the second scan line 152 at the same time as the signal of the first scan line 151.

For example, when a negative voltage is applied to the first scan line 151, a positive voltage may be applied to the second scan line 152.

The second scan line 152 transmits the second scan signal SS to the third transistor T3.

The third scan line 153 transmits the initialization control signal SI to the fourth transistor T4.

The light emission control line 155 transmits the light emitting control signal EM to the fifth transistor T5 and a sixth transistor T6.

The data line 171 is a wire that transmits the data voltage DAT, and, accordingly, a size of a light emitting current transmitted to the light emitting element LED changes, and a luminance emitted by the light emitting element LED also changes.

The driving voltage line 172 applies the driving voltage ELVDD.

The initialization voltage line 173 delivers an initialization voltage INIT.

The common voltage line 741 applies the common voltage ELVSS to the cathode of the light emitting element LED (e.g., light emitting diode (LED)).

In an embodiment, the voltage applied to the driving voltage line 172, the initialization voltage line 173, and the common voltage line 741 may each be a constant voltage.

In an embodiment, a transistor adjusts the size of the light emitting current output to the anode of the light emitting diode (LED) according to the size of the voltage of the gate electrode of the driving transistor T1 (i.e., the voltage stored in the storage capacitor Cst).

The brightness of the light emitting diode (LED) is adjusted according to the size of the light emitting current output to the anode electrode of the light emitting diode (LED), and the light emitting brightness of the light emitting diode (LED) can be adjusted according to the data voltage DAT applied to the pixel.

To this end, the first electrode of the driving transistor T1 is arranged to receive the driving voltage ELVDD and is connected to the driving voltage line 172 via the fifth transistor T5.

Additionally, the first electrode of the driving transistor T1 is connected to the second electrode of the second transistor T2 to receive the data voltage DAT.

The second electrode of the driving transistor T1 outputs a light emitting current to the light emitting diode (LED) and is connected to the anode of the light emitting diode (LED) via the sixth transistor T6 (herein also referred to as the output control transistor).

Additionally, the second electrode of the driving transistor T1 is connected to the third transistor T3 and transmits the data voltage DAT applied to the first electrode to the third transistor T3.

The gate electrode of the driving transistor T1 is connected to one electrode (herein referred to as the “second storage electrode”) of the storage capacitor Cst.

Accordingly, a voltage of the gate electrode of the driving transistor T1 changes according to a voltage stored in the storage capacitor Cst, and the light emitting current output by the driving transistor T1 changes accordingly.

The storage capacitor Cst serves to keep the voltage of the gate electrode of the driving transistor T1 constant during one frame.

The gate electrode of the driving transistor T1 is also connected to the third transistor T3, such that the data voltage DAT applied to the first electrode of the driving transistor T1 passes through the third transistor T3 to the gate electrode of the driving transistor T1.

The gate electrode of the driving transistor T1 is also connected to the fourth transistor T4 and can be initialized by receiving the initialization voltage INIT.

The second transistor T2 is a transistor that receives the data voltage DAT into the pixel.

The gate electrode of the second transistor T2 is connected to the first scan line 151 and one electrode of the boost capacitor Cboost (herein referred to as “lower boost electrode”).

The first electrode of the second transistor T2 is connected to the data line 171.

The second electrode of the second transistor T2 is connected to the first electrode of the driving transistor T1.

When the second transistor T2 is turned on by the negative voltage of the first scan signal SC transmitted through the first scan line 151, the data voltage DAT transmitted through the data line 171 is transmitted to the first electrode of the driving transistor T1, and, finally, the data voltage DAT is transmitted to the gate electrode of the driving transistor T1 and stored in the storage capacitor Cst.

The third transistor T3 electrically connects the second electrode of the driving transistor T1 to the gate electrode of the driving transistor T1.

As a result, the data voltage DAT is compensated by the threshold voltage of the driving transistor T1 and then stored in the second storage electrode of the storage capacitor Cst.

The gate electrode of the third transistor T3 is connected to the second scan line 152, and the first electrode of the third transistor T3 is connected to the second electrode of the driving transistor T1.

The second electrode of the third transistor T3 is connected to the second storage electrode of the storage capacitor Cst, the gate electrode of the driving transistor T1, and the other electrode (herein referred to as “upper boost electrode”) of the boost capacitor Cboost.

The third transistor T3 is turned on by the positive voltage of the second scan signal SS received through the second scan line 152, and the gate electrode of the driving transistor T1 and the second electrode are connected, and the voltage applied to the gate electrode of the driving transistor T1 is transferred to the second storage electrode of the storage capacitor Cst and stored in the storage capacitor Cst.

At this time, the voltage stored in the storage capacitor Cst is the voltage of the gate electrode of the driving transistor T1 when the driving transistor T1 is turned off, such that the threshold voltage (Vth) value of the driving transistor T1 is stored in a compensated state.

The fourth transistor T4 serves to initialize the gate electrode of the driving transistor T1 and the second storage electrode of the storage capacitor Cst.

The gate electrode of the fourth transistor T4 is connected to the third scan line 153, and the first electrode of the fourth transistor T4 is connected to the initialization voltage line 173.

The second electrode of the fourth transistor T4 is connected to the second electrode of the third transistor T3, the second storage electrode of the storage capacitor Cst, the gate electrode of the driving transistor T1, and the upper boost electrode of the boost capacitor Cboost.

The fourth transistor T4 is turned on by the positive polarity voltage of the initialization control signal SI received through the third scan line 153, at which time the initialization voltage INIT is applied to the driving transistor T1. It is initialized by being passed to the gate electrode, the second storage electrode of the storage capacitor Cst, and the upper boost electrode of the boost capacitor Cboost.

The fifth transistor T5 serves to transmit the driving voltage ELVDD to the driving transistor T1.

The gate electrode of the fifth transistor T5 is connected to the light emission control line 155, the first electrode of the fifth transistor T5 is connected to the driving voltage line 172, the first electrode of the fifth transistor T5 is connected to the driving voltage line 172, and the second electrode is connected to the first electrode of the driving transistor T1.

The sixth transistor T6 serves to transfer the light emitting current output from the driving transistor T1 to the light emitting diode (LED).

The gate electrode of the sixth transistor T6 is connected to the light emission control line 155, the first electrode of the sixth transistor T6 is connected to the second electrode of the driving transistor T1, and the second electrode of the sixth transistor T6 is connected to the anode of the light emitting diode (LED).

The seventh transistor T7 serves to initialize the anode of the light emitting diode (LED).

The gate electrode of the seventh transistor T7 is connected to the first scan line 151, the first electrode of the seventh transistor T7 is connected to the anode of the light emitting diode (LED), and the second electrode of the seventh transistor T7 is connected to the initialization voltage line 173.

Here, the gate electrode of the seventh transistor T7 is connected to the first scan line 151 of the previous pixel, and the first scan line 151 is the same as the gate electrode of the second transistor T2 belonging to the front pixel PX, but may be connected to the first scan line 151, which is the same as the gate electrode of the second transistor T2 of the front pixel PX.

When the seventh transistor T7 is turned on by the negative voltage of the first scan line 151, the initialization voltage INIT is applied to the anode of the light emitting diode (LED) and initialized.

The gate electrode of the seventh transistor T7 may be connected to a separate bypass control line through which a bypass signal is transmitted, and may be controlled through a line separate from the first scan line 151.

Additionally, depending on the embodiment, the initialization voltage line 173 to which the initialization voltage INIT is applied may be the same as the initialization voltage line 173 to which the initialization voltage INIT is applied.

A single pixel PX is described as including seven transistors T1 to T7 and two capacitors (storage capacitor Cst, boost capacitor Cboost), but embodiments are not limited thereto, and depending on an embodiment, the boost capacitor Cboost may be excluded.

The structure of the pixel PX included in the display device according to an embodiment may be applied to the circuit diagrams shown in FIGS. 2, 10, and 11, and may have various pixel structures depending on the type of display device.

In an embodiment, each transistor T1, T2, T3, T4, T5, T6, and T7 may have the structure of the transistor of FIGS. 3 to 6 described above.

Although some embodiments have been described above, the scope of the present invention is not limited thereto, and various modifications and improvements made by those skilled in the art using the basic concepts of the present invention as set forth in the following claims are possible.

What is claimed is:

1. A display device comprising:
a barrier layer on a substrate and comprising a trench;
a first buffer layer on the barrier layer and arranged along a profile of the trench;
a second buffer layer on the first buffer layer and arranged along a profile of the first buffer layer;
a semiconductor layer on the second buffer layer and comprising a channel region overlapping the trench;
a gate insulating layer on the semiconductor layer and overlapping the channel region; and
a gate electrode on the gate insulating layer and overlapping the channel region,
wherein the first buffer layer has a thickness that is thinner than a thickness of the second buffer layer.

2. The display device of claim 1, wherein
the trench comprises a vertical portion connecting a portion having a thinnest thickness of the barrier layer and a portion having a thickest thickness of the barrier layer,
the channel region has a depth corresponding to the vertical portion of the trench, and
the depth of the channel region is 330 Å to 3500 Å.

3. The display device of claim 2, wherein the channel region has a width of 5 μm or less.

4. The display device of claim 1, wherein the first buffer layer comprises a material of which an amount of hydrogen emission increases as a stack thickness increases.

5. The display device of claim 1, wherein the second buffer layer comprises a material of which an amount of hydrogen emission is constant as a stack thickness increases.

6. The display device of claim 1, wherein the first buffer layer comprises silicon nitride, and the second buffer layer comprises silicon oxide.

7. The display device of claim 6, wherein the first buffer layer has a thickness of 330 Å to 1100 Å, and the second buffer layer has a thickness of 1600 Å to 2400 Å.

8. The display device of claim 1, wherein the gate insulating layer has a thickness of 650 Å or more and 2000 Å or less.

9. The display device of claim 1, wherein corner portions of the trench have a rounded shape.

10. The display device of claim 1, wherein the gate insulating layer comprises at least one of Al₂O₃, TiO₂, and HfO₂.

11. A display device comprising:
a barrier layer on a substrate and comprising a fin structure;
a first buffer layer on the barrier layer and arranged along a profile of the fin structure;
a second buffer layer on the first buffer layer and arranged along a profile of the first buffer layer;
a semiconductor layer on the second buffer layer and comprising a channel region overlapping the fin structure;
a gate insulating layer on the semiconductor layer and overlapping the channel region; and
a gate electrode on the gate insulating layer and overlapping the channel region,
wherein the first buffer layer has a thickness that is thinner than a thickness of the second buffer layer.

12. The display device of claim 11, wherein
the fin structure comprises a vertical portion connecting a portion having a thinnest thickness of the barrier layer and a portion having a thickest thickness of the barrier layer,
the channel region has a depth corresponding to the vertical portion of the fin structure, and
the depth of the channel region is 330 Å to 3500 Å.

13. The display device of claim 12, wherein the channel region has a width of 5 μm or less.

14. The display device of claim 11, wherein the first buffer layer comprises a material of which an amount of hydrogen emission increases as a stack thickness increases.

15. The display device of claim 11, wherein the second buffer layer comprises a material of which a hydrogen emission amount is constant as a stack thickness increases.

16. The display device of claim 11, wherein the first buffer layer comprises silicon nitride, and the second buffer layer comprises silicon oxide.

17. The display device of claim 16, wherein the first buffer layer has a thickness of 450 Å or less, and the second buffer layer has a thickness of 1000 Å to 2000 Å.

18. The display device of claim 11, wherein the gate insulating layer has a thickness of 650 Å or more and 2000 Å or less.

19. The display device of claim 11, wherein a corner portion of the fin structure includes a rounded shape.

20. The display device of claim 11, wherein the gate insulating layer comprises at least one of Al₂O₃, TiO₂, and HfO₂.
